(19) United States
(12) Patent Application Publication
(10) Pub. No.: US 2014/0332767 A1
(43) Pub. Date: Nov. 13, 2014

(54) THIN FILM TRANSISTOR AND ORGANIC LIGHT EMITTING DIODE DISPLAY INCLUDING THE SAME

(71) Applicant: Samsung Display Co., Ltd., Yongin-City (KR)

(72) Inventors: Guang-Hai JIN, Yongin-City (KR); Jae-Beom CHOI, Yongin-City (KR); Won-Kyu LEE, Yongin-City (KR); Seong-Hyun JIN, Yongin-City (KR)

(73) Assignee: Samsung Display Co., Ltd., Yongin-City (KR)

(21) Appl. No.: 14/024,453

(22) Filed: Sep. 11, 2013

(30) Foreign Application Priority Data
May 9, 2013 (KR) 10-2013-0052587

(51) Int. Cl. H01L 29/786; H01L 27/32

(52) U.S. Cl. CPC H01L 29/786; H01L 27/3244
USPC 257/40; 257/288

(57) ABSTRACT

A thin film transistor is disclosed. The thin film transistor may include a semiconductor formed on a substrate, a gate insulating layer formed on the semiconductor, a gate electrode formed on the gate insulating layer and including a plurality of branches overlapping the semiconductor, an interlayer insulating layer at least partially overlapping the gate electrode, and a repair pattern formed on the interlayer insulating layer. The repair pattern may be formed overlapping the branches. The repair pattern may also be formed in a closed loop.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57. For example, this application claims priority to and the benefit of Korean Patent Application No. 10-2013-0052587 filed in the Korean Intellectual Property Office on May 9, 2013, the entire contents of which are incorporated herein by reference.

### BACKGROUND

1. Field

The present disclosure relates to a thin film transistor and an organic light emitting diode (OLED) display including the same.

2. Description of Related Technology

In general, a thin film transistor (TFT) array panel is used as a circuit board for independently driving each pixel in a liquid crystal display, an organic electroluminescence (EL) display device, or the like. The thin film transistor substrate is formed of a scan signal wire transmitting a scan signal or a gate wire, an image signal wire transmitting an image signal or a data wire, a thin film transistor electrically connected to the gate wire and the data wire, a first electrode electrically connected to the thin film transistor, a gate insulating layer insulating the gate wire by covering the same, and an interlayer insulating layer insulating the thin film transistor and the data wire by covering the same. The thin film transistor is formed of a gate electrode part of the gate wire, a semiconductor forming a channel, a source electrode and a drain electrode that are portions of the data wire, a gate insulating layer, and an interlayer insulating layer. The thin film transistor is a switching element capable of transmitting an image signal transmitted through the data wire according to the scan signal transmitted through the gate wire to a first electrode or interrupting the transmission of the image signal.

In the thin film transistor substrate, residue from particles generated in the manufacturing process may speed deterioration of the thin film transistor. When this occurs, defects may be visible in a corresponding pixel such that a repair process is required. When a defect is detected by the naked eye, the defective portion may be easily repaired. However, a short defect caused by a fine particle or static electricity is difficult to detect with the naked eye, thus complicating repair. Meanwhile, to increase a channel length of the transistor, a plurality of gate electrodes may be used. When a defect occurs in one gate electrode among the plurality of gate electrodes, one gate electrode may be randomly disconnected such that remaining gate electrodes are used to drive the transistor. However, when disconnecting the normal gate electrode, other gate electrodes are disconnected such that the transistor operates poorly and results in a defective pixel.

The above information disclosed in this Background section is only for enhancement of understanding of the background of the disclosure, and therefore, it may contain information that does not form the prior art already known in this country to a person of ordinary skill in the art.

### SUMMARY OF CERTAIN INVENTIVE ASPECTS

In one aspect, a thin film transistor and a repair method thereof are provided. In some embodiments, the repair method can easily perform a repair even when a defect is difficult to detect by the naked eye is generated.

In another aspect, a thin film transistor is provided. The thin film transistor may include, for example, a semiconductor formed on a substrate, a gate insulating layer formed on the semiconductor, a gate electrode formed on the gate insulating layer and including a plurality of branches at least partially overlapping the semiconductor, an interlayer insulating layer at least partially overlapping the gate electrode, and a repair pattern formed on the interlayer insulating layer.

In some embodiments, the repair pattern is formed overlapping the branches. In some embodiments, the repair pattern is formed in a closed loop. In some embodiments, the branches may include a repair part and an electrode part, the electrode part may overlap the semiconductor, and the repair pattern may overlap the repair part. In some embodiments, one of the branches may be short-circuited by the repair pattern. In some embodiments, one of the branches is electrically disconnected. In some embodiments, the semiconductor may include a source region, a drain region, and a channel region, and a source electrode and a drain electrode positioned on the interlayer insulating layer and electrically connected to the source region and the drain region may be further included.

In another aspect, an organic light emitting diode (OLED) display is provided. The OLED may include, for example, a substrate, a thin film transistor formed on the substrate, a first electrode electrically connected to the thin film transistor, an organic emission layer formed on the first electrode, and a second electrode formed on the organic emission layer.

In some embodiments, the thin film transistor includes, for example, a semiconductor formed on the substrate, a gate insulating layer formed on the semiconductor, a gate electrode formed on the gate insulating layer and including a plurality of branches overlapping the semiconductor, an interlayer insulating layer overlapping the gate electrode, and a repair pattern formed on the interlayer insulating layer, overlapping the branches, and forming a closed loop. In some embodiments, the branches may include a repair part and an electrode part. In some embodiments, the electrode part may overlap the semiconductor. In some embodiments, the repair pattern may overlap the repair part. In some embodiments, one of the branches is short-circuited by the repair pattern. In some embodiments, one of the branches may be electrically disconnected.

In another aspect, although the thin film transistor may be damaged by particles, a repair pattern is provided herein to more easily repair the thin film transistor than other methods known in the art.

### BRIEF DESCRIPTION OF THE DRAWINGS

Features of the present disclosure will become more fully apparent from the following description and appended claims, taken in conjunction with the accompanying drawings. It will be understood these drawings depict only certain embodiments in accordance with the disclosure and, therefore, are not to be considered limiting of its scope; the disclosure will be described with additional specificity and detail through use of the accompanying drawings. An apparatus, system or method according to some of the described embodiments can have several aspects, no single one of which necessarily is solely responsible for the desirable attributes of the apparatus, system or method. After considering this discussion, and particularly after reading the section entitled “Detailed Description of Certain Inventive Embodiments” one will understand how illustrated features serve to explain certain principles of the present disclosure.

FIG. 1 is a layout view of a thin film transistor according to an exemplary embodiment.

FIG. 2 is a cross-sectional view taken along the line II-II of FIG. 1.

FIG. 3 is a flowchart of a method of repairing a thin film transistor according to an exemplary embodiment.

FIG. 4 and FIG. 5 are layout views of a middle step of repairing a thin film transistor.

FIG. 6 is an equivalent circuit of one pixel of an organic light emitting diode (OLED) display according to the present disclosure.

FIG. 7 is a layout view of an organic light emitting diode (OLED) display according to an exemplary embodiment.

FIG. 8 is a cross-sectional view taken along the line VIII-VIII of FIG. 7.

FIG. 9 is a cross-sectional view taken along the line IX-IX of FIG. 7.

### DETAILED DESCRIPTION OF CERTAIN INVENTIVE EMBODIMENTS

The present invention will be described more fully hereinafter with reference to the accompanying drawings, in which exemplary embodiments are shown. As those skilled in the art would realize, the described embodiments may be modified in various different ways, all without departing from the spirit or scope of the present invention. In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. Now, a thin film transistor and a thin film transistor display panel including the same according to exemplary embodiments will be described with reference to accompanying drawings.

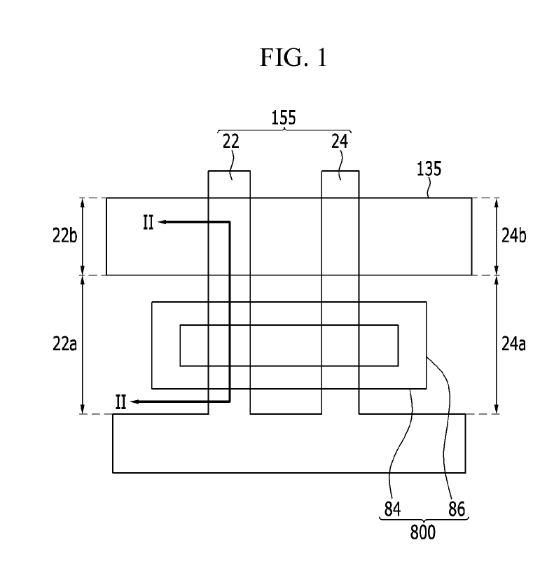

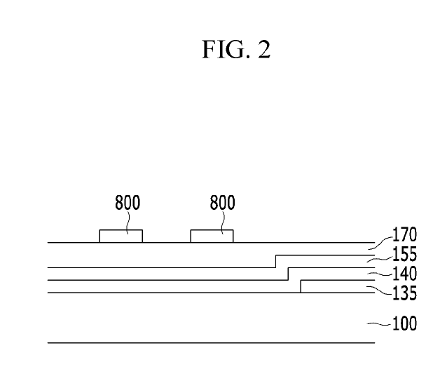

FIG. 1 is a layout view of a thin film transistor according to an exemplary embodiment, and FIG. 2 is a cross-sectional view taken along the line II-II of FIG. 1. Referring to FIG. 1 and FIG. 2, a thin film transistor according to some embodiments of the present disclosure includes a semiconductor 135 positioned on a substrate 100, a gate insulating layer 140 positioned on the semiconductor 135, a gate electrode 155 positioned on the gate insulating layer 140, an interlayer insulating layer 170 positioned on the gate electrode 155, and a repair pattern 800, a source electrode (not shown), and a drain electrode (not shown) positioned on the interlayer insulating layer 170.

The semiconductor 135 may be made of polysilicon, microcrystalline silicon, or amorphous silicon. The semiconductor 135 made of polysilicon includes a channel region in which conductive impurities are not doped, and a source region and a drain region doped with conductive impurities at a high concentration. The impurity doped in the source region and the drain region may be one of a p-type impurity and an n-type impurity.

The gate insulating layer 140 may be a single layer or a plurality of layers including at least one of tetraethoxysilane (tetraethyl orthosilicate, TEOS), silicon nitride, and silicon oxide. The gate electrode 155 includes first branches 22 and second branches 24, and the first branches 22 and the second branches 24 respectively include repair parts 22a and 24a and electrode parts 22b and 24b. The repair parts 22a and 24a overlap the repair pattern 800, and the electrode parts 22b and 24b overlap the semiconductor 135. Like the gate insulating layer 140, the interlayer insulating layer 170 may be made of tetraethoxysilane (tetraethyl orthosilicate, TEOS), silicon nitride, or silicon oxide.

The repair pattern 800 includes a pair of transverse lines 84 respectively overlapping the repair parts 22a and 24a, and the transverse lines 84 are disposed in a direction intersecting a direction that a gate signal passes. A pair of transverse lines 84 is separated, and when disconnecting a defective gate electrode, the gate electrode positioned between the transverse lines 84 is disconnected by using a laser. A pair of transverse lines may be positioned separated by a predetermined distance for the transverse line 84 to not be damaged by the laser. The transverse lines 84 are electrically connected by a pair of longitudinal lines 86 thereby forming a closed loop. Each longitudinal line 86 connects one end of the transverse line 84 and does not overlap the first branches 22 and the second branches 24.

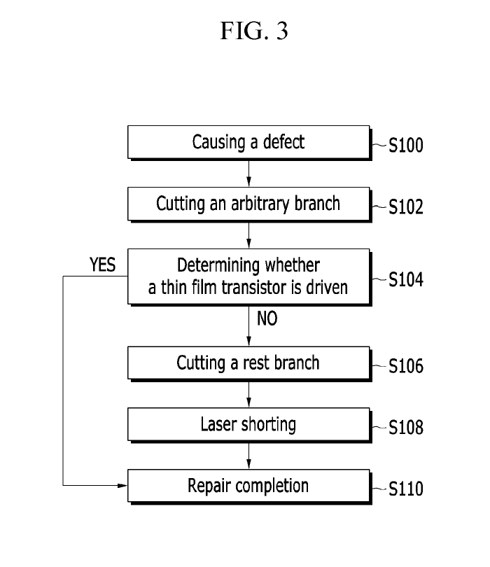

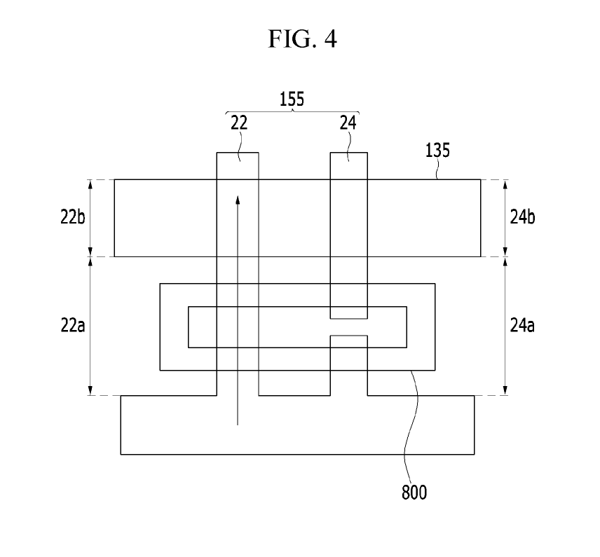

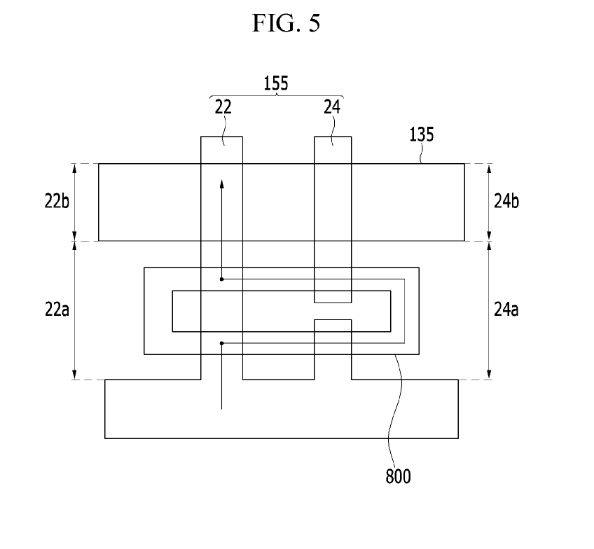

Next, a method of repairing the thin film transistor of FIG. 1 will be described in detail with reference to FIG. 3. FIG. 3 is a flowchart of a method of repairing a thin film transistor according to an exemplary embodiment, and FIG. 4 and FIG. 5 are layout views of a middle step of repairing a thin film transistor. For better understanding and ease of description, as an example, it is assumed that a particle remains at the first branches 22 of the thin film transistor of FIG. 1 such that a defect is generated.

Referring to FIG. 3, if a defect is generated (S100), a gate electrode 155 of a thin film transistor is disconnected (S102). The branch in which the defect is generated may be difficult to distinguish by the naked eye such that one branch among the first branches 22 or the second branches 24 may be disconnected. Next, it is determined whether the thin film transistor is operated by driving the thin film transistor (S104). If the thin film transistor is normally operated, the first branch 22 that is defective is disconnected such that the repair is completed (S110). As shown in FIG. 4, if the first branch 22 in which the defect is generated is correctly disconnected, the gate signal is transmitted through the second branch 24 such that the repair is completed. However, if the thin film transistor is still abnormally operated, the second branches 24 as the remaining branch not previously disconnected is disconnected (S106). Then, the second branches 24, which are not defective, are disconnected such that the thin film transistor is defective. Next, the second branches 24 and the repair pattern 800 are shorted by using the laser (S108) to complete the repair (S110). In the short using the laser, the repair pattern 800 and the second branches 24 that are positioned upward and downward with respect to the disconnected portion of the second branch 24 are short-circuited.

In this way, if the second branches 24 are disconnected and shorted by using the repair pattern 800, as shown in FIG. 5, the gate signal may be transmitted to the electrode part 24a through the repair pattern 800. In an exemplary embodiment, by forming the repair pattern 800 of the closed-loop shape and by overlapping the repair pattern 800 to the gate electrode 155, although the branch of the gate electrode applied with the normal signal is disconnected when performing the disconnection using the laser, the gate signal may be transmitted through the repair pattern thereby easily obtaining the repair.

Next, an organic light emitting diode (OLED) display including the above transistor will be described in detail.

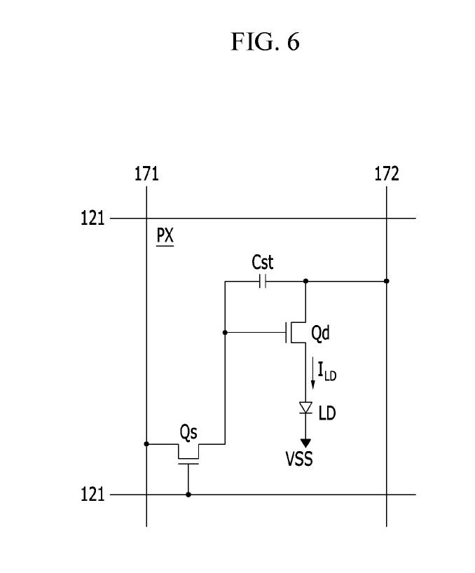

FIG. 6 is an equivalent circuit of one pixel of an organic light emitting diode (OLED) display according to some embodiments of the present disclosure. As shown in FIG. 6, the organic light emitting diode display according to the exemplary embodiment includes a plurality of signal lines 121, 171, and 172 and pixels PX connected thereto.

The signal lines include a scan signal line 121 transferring a gate signal (or a scan signal), a data line 171 transferring a data signal, a driving voltage line 172 transferring a driving voltage, and the like. The scan signal lines 121 extend in an approximate row direction and are parallel to each other, and the data lines 171 extend in an approximate column direction and are almost parallel to each other. The driving voltage line 172 extending in an approximate column direction is shown, but the driving voltage line 172 may extend in a row direction or a column direction or may have a mesh form.

Each pixel PX includes a switching transistor Qs, a driving transistor Qd, a storage capacitor Cst, and an organic light emitting element LD. The switching transistor Qs includes a control terminal, an input terminal, and an output terminal, and the control terminal is connected to a scan signal 121, the input terminal is connected to a data line 171, and the output terminal is connected to a driving transistor Qd. The switching transistor Qs transmits a data signal received from the data line 171 to the driving transistor Qd in response to a scan signal received from the scanning signal line 121. The driving transistor Qd also includes a control terminal, an input terminal, and an output terminal, and the control terminal is connected to the switching transistor Qs, the input terminal is connected to a driving voltage line 172, and the output terminal is connected to an organic light emitting element LD. The driving transistor Qd generates an output current ILD. The intensity of the output current ILD varies depending on the voltage between the control terminal and the output terminal thereof.

The capacitor Cst is connected between the control terminal and the input terminal of the driving transistor Qd. The capacitor Cst charges a data signal applied to the control terminal of the driving transistor Qd and maintains the charged data signal even after the switching transistor Qs is turned off. As an organic light emitting diode (OLED), the organic light emitting element LD, for example, includes an anode connected to the output terminal of the driving transistor Qd and a cathode connected to a common voltage Vss. The organic light emitting element LD displays an image by changing intensity thereof depending on the output current ILD of the driving transistor Qd. The organic light emitting element LD may include an organic emission layer which uniquely emits any one or one or more light of primary colors such as three primary colors of red, green, and blue, and displays a desired image in a spatial combination of the colors. The switching transistor Qs and the driving transistor Qd are n-channel field effect transistors (FETs), however at least one may be a p-channel FET. In some embodiments, the electrical connections among the transistors Qs and Qd, the capacitor Cst, and the organic light emitting diode LD may be modified.

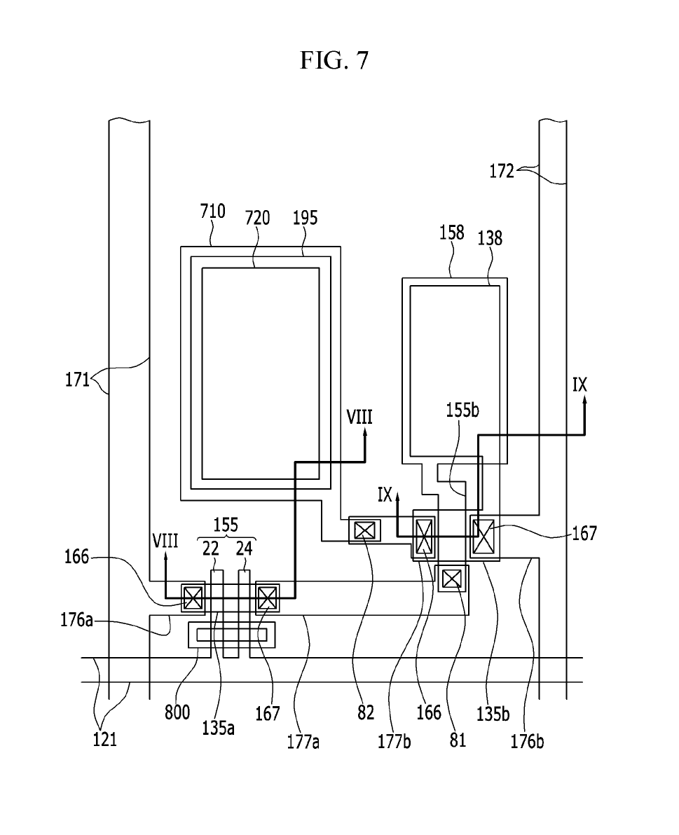

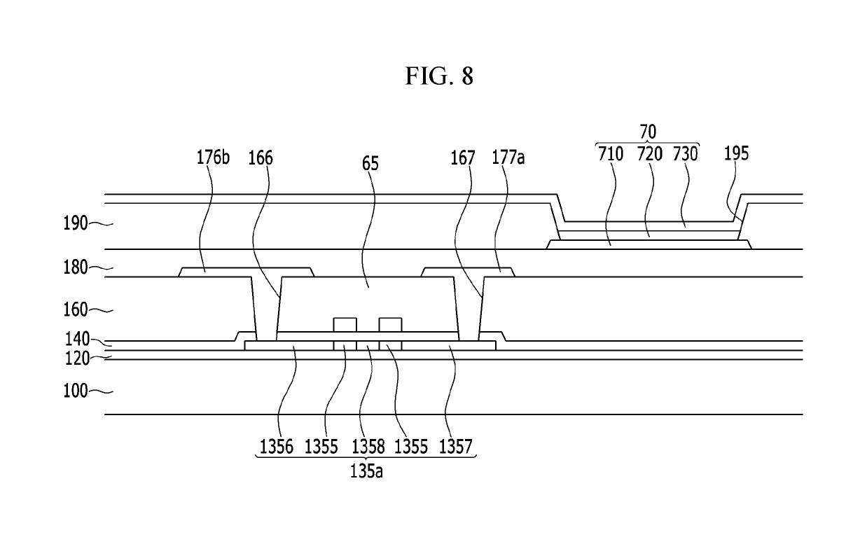

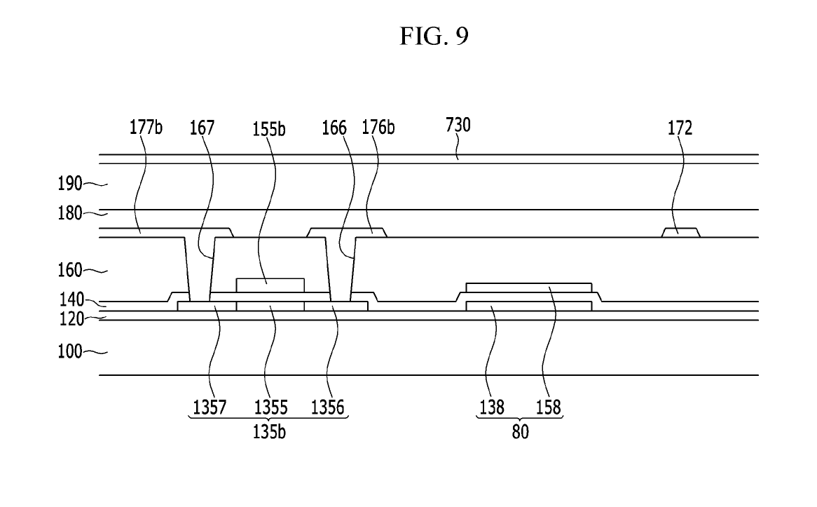

FIG. 7 is a layout view of an organic light emitting diode (OLED) display according to an exemplary embodiment, FIG. 8 is a cross-sectional view taken along the line VIII-VIII of FIG. 7, and FIG. 9 is a cross-sectional view taken along the line IX-IX of FIG. 7.

As shown in FIG. 7 to FIG. 9, a buffer layer 120 is formed on the substrate 100. The substrate 100 may be an insulating material formed of glass, quartz, ceramic, or plastic, or the substrate 100 may be a metallic substrate formed of stainless steel. The buffer layer 120 may have a single-layered structure of silicon nitride (SiNx), or a double-layered structure of silicon nitride (SiNx) and silicon oxide (SiO2). The buffer layer 120 has a role of preventing unwanted components like impure elements or moisture from intruding into the target, while flattening the surface thereof at the same time. In some embodiments, a first semiconductor 135a, a second semiconductor 135b, and a first capacitor electrode 138 may be formed of polysilicon and/or may be formed on the buffer layer 120. The first semiconductor 135a and the second semiconductor 135b, respectively, may include a channel region 1355, and a source region 1356 and a drain region 1357 formed at respective sides of the channel region 1355. The channel region 1355 of the semiconductors 135a and 135b may be formed of polysilicon that is not doped with an impurity, that is, an intrinsic semiconductor. The source region 1356 and the drain region 1357 of the semiconductors 135a and 135b may be formed of polysilicon that is doped with the conductive impurity, that is, an impurity semiconductor.

In some embodiments, the first semiconductor 135a has two channel regions 1355, and a high concentration doping region 1358 that becomes the source region and the drain region is positioned between two channel regions. The first capacitor electrode 138 is doped with the same conductive impurity as the source region 1356 and the drain region 1357. The impurity doped in the source region 1356 and the drain region 1357, the high concentration doping region 1358, and the first capacitor electrode 138 may be one of the p-type impurity and the n-type impurity.

The gate insulating layer 140 is formed on the first semiconductor 135a, the second semiconductor 135b, and the first capacitor electrode 138. The gate insulating layer 140 may be a single layer or a plurality of layers including at least one of tetraethoxysilane (tetraethyl orthosilicate, TEOS), silicon nitride, and silicon oxide.

A gate line 121, a second gate electrode 155b, and a second capacitor electrode 158 are formed on the gate insulating layer 140. The gate line 121 extends in a transverse direction, transmits the gate signal, and includes a first gate electrode 155a protruding from the first semiconductor 135a. As shown in FIG. 1, the first gate electrode 155a includes the first branch 22 and the second branch 24.

The first gate electrode 155a and the second gate electrode 155b respectively overlap the channel region 1355. The first gate electrode 155a, the second gate electrode 155b, and the second capacitor electrode 158 may be formed of a single layer of a multiple layer of tungsten, molybdenum, aluminum, or an alloy thereof. The second capacitor electrode 158 is connected to the second gate electrode 155b and overlaps the first capacitor electrode 138. The first capacitor electrode 138 and the second capacitor electrode 158 form a capacitor 80 having the gate insulating layer 140 as a dielectric material.

A first interlayer insulating layer 160 is formed on the gate line 121, the second gate electrode 155b, and a repairing conductor 202. The first interlayer insulating layer 160 may be formed of tetraethoxysilane (tetraethyl orthosilicate, TEOS), silicon nitride, or silicon oxide like the gate insulating layer 140. The first interlayer insulating layer 160 and the gate insulating layer 140 have a source contact hole 166 and a drain contact hole 167 respectively exposing the source region 1356 and the drain region 1357, and a contact hole 81 exposing the second gate electrode 155b.

A data line 171 having a first source electrode 176a, a driving voltage line 172 having a second source electrode 176b, a first drain electrode 177a, and a second drain electrode 177b are formed on the first interlayer insulating layer 160. The repair pattern 800 overlapping the first gate electrode 155a is formed on the first interlayer insulating layer 160. The data line 171 transmits the data signal and extends in a direction intersecting the gate line 121. The driving voltage line 172 transmits a predetermined voltage, is separated from the data line 171, and extends in the same direction as the data line 171. The first source electrode 176a is protruded from the data line 171 toward the first semiconductor 135a, and the second source electrode 176b is protruded from the driving voltage line 172 toward the second semiconductor 135b. The first source electrode 176a and the second source electrode 176b are respectively connected to the source region 1356 through the source contact hole 166. The first drain electrode 177a faces the first source electrode 176a, the second drain electrode 177b faces the second source electrode 176b, and the first drain electrode 177a and the second drain electrode 177b are respectively connected to the drain region 1357 through the drain contact hole 167. The first drain electrode 177a extends according to the gate line, and is electrically connected to the second gate electrode 155b through the contact hole 81.

A capacitor electrode (not shown) may be further formed on the first interlayer insulating layer 160. The additional capacitor electrode may overlap the first capacitor electrode 138 or the second capacitor electrode 158 to be connected in parallel thereby increasing charging capacitance.

A second interlayer insulating layer 180 is formed on the data line 171 having the first source electrode 176a, the driving voltage line 172 having the second source electrode 176b, the first drain electrode 177a, the second drain electrode 177b, and the repair pattern 800. The second interlayer insulating layer 180 may be formed of the same material as the first interlayer insulating layer 160 and has a contact hole 82 exposing the second drain electrode 177b.

A first electrode 710 is formed on the second interlayer insulating layer 180. The first electrode 710 may be the anode of FIG. 6.

A pixel definition layer 190 having an opening 195 exposing the first electrode 710 is formed on the first electrode 710. The pixel defining layer 190 may be formed by including a resin such as a polyacrylate or a polyimide, or a silica-based inorganic material.

An organic emission layer 720 is formed in the opening 195 of the pixel defining layer 190. The organic emission layer 720 includes an emission layer, and may include at least one of a hole transport layer (HTL), a hole-injection layer (HIL), an electron transport layer (ETL), and an electron injection layer (EIL). In the case where the organic emission layer 720 includes all of them, the hole injection layer (HIL) may be disposed on the first electrode 710 that is the anode, and the hole transport layer (HTL), the emission layer, the electron transport layer (ETL), and the electron injection layer (EIL) may be sequentially laminated thereon.

A second electrode 730 may be formed on the pixel definition layer 190 and the organic emission layer 720. The second electrode 730 becomes a cathode of the organic light emitting element. Accordingly, the first electrode 710, the organic emission layer 720, and the second electrode 730 may form an organic light emitting element 70. The second electrode 730 may be formed of a reflective layer, a transparent layer, and/or a semi-transparent layer.

The reflective layer and semi-transparent layer may be formed of at least one of magnesium (Mg), silver (Ag), gold (Au), calcium (Ca), lithium (Li), chromium (Cr), and aluminum (Al), or alloys thereof. The reflective layer and the semi-transparent layer may be selected based on thickness. In some embodiments, the semi-transparent layer may have a thickness of less than or equal to 200 nm. Light transmittance is increased as the thickness is decreased, but resistance is increased when the thickness decreases. The transparent layer may be formed of a material such as indium tin oxide (ITO), indium zinc oxide (IZO), and zinc oxide (ZnO).

While this invention has been described in connection with what are presently considered to be practical exemplary embodiments, it will be appreciated by those skilled in the art that various modifications and changes may be made without departing from the scope of the present disclosure. It will also be appreciated by those of skill in the art that parts included in one embodiment are interchangeable with other embodiments; one or more parts from a depicted embodiment can be included with other depicted embodiments in any combination. For example, any of the various components described herein and/or depicted in the Figures may be combined, interchanged or excluded from other embodiments. With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity. Thus, while the present disclosure has described certain exemplary embodiments, it is to be understood that the invention is not limited to the disclosed embodiments, but, on the contrary, is intended to cover various modifications and equivalent arrangements included within the spirit and scope of the appended claims.

What is claimed is:

1. A thin film transistor, comprising:
a semiconductor formed on a substrate;
a gate insulating layer formed on the semiconductor;
a gate electrode formed on the gate insulating layer, the gate electrode including a plurality of branches formed overlapping the semiconductor;
an interlayer insulating layer formed overlapping the gate electrode; and
a repair pattern formed on the interlayer insulating layer, the repair pattern forming a closed loop.

2. The thin film transistor of claim 1, wherein the plurality of branches includes a repair part and an electrode part.

3. The thin film transistor of claim 2, wherein the electrode part partially overlaps the semiconductor, and wherein the repair pattern partially overlaps the repair part.

4. The thin film transistor of claim 1, wherein one of the plurality branches is short-circuited by the repair pattern.

5. The thin film transistor of claim 1, wherein one of the plurality of branches is electrically disconnected.

6. The thin film transistor of claim 1, wherein the semiconductor includes a source region, a drain region, and a channel region.

7. The thin film transistor of claim 6, wherein the semiconductor further includes a source electrode and a drain electrode formed on the interlayer insulating layer.

8. The thin film transistor of claim 6, wherein the source electrode and the drain electrode are electrically connected to the source region and the drain region, respectively.

9. An organic light emitting diode (OLED) display, comprising:
a substrate;
a thin film transistor formed on the substrate;
a first electrode electrically connected to the thin film transistor;
an organic emission layer formed on the first electrode; and
a second electrode formed on the organic emission layer,
wherein the thin film transistor includes:
a semiconductor positioned on the substrate,
a gate insulating layer formed on the semiconductor,
a gate electrode formed on the gate insulating layer and including a plurality of branches overlapping the semiconductor,
an interlayer insulating layer formed at least partially overlapping the gate electrode, and
a repair pattern formed on the interlayer insulating layer overlapping the branches, the repair pattern forming a closed loop.

10. The organic light emitting diode (OLED) display of claim 9, wherein the plurality of branches includes a repair part and an electrode part, wherein the electrode part overlaps the semiconductor, and wherein the repair pattern overlaps the repair part.

11. The organic light emitting diode (OLED) display of claim 9, wherein one of the plurality of branches is short-circuited by the repair pattern.

12. The organic light emitting diode (OLED) display of claim 9, wherein one of the plurality of branches is electrically disconnected.

13. An organic light emitting diode (OLED) display, comprising:
the thin film transistor of claim 1;
a first electrode electrically connected to the thin film transistor;
an organic emission layer formed on the first electrode; and
a second electrode formed on the organic emission layer.

14. The organic light emitting diode (OLED) display of claim 13, wherein the plurality of branches includes a repair part and an electrode part.

15. The organic light emitting diode (OLED) display of claim 14, wherein the electrode part partially overlaps the semiconductor, and wherein the repair pattern partially overlaps the repair part.

16. The organic light emitting diode (OLED) display of claim 13, wherein one of the plurality branches is short-circuited by the repair pattern.

17. The organic light emitting diode (OLED) display of claim 13, wherein one of the plurality of branches is electrically disconnected.

18. The organic light emitting diode (OLED) display of claim 13, wherein the semiconductor includes a source region, a drain region, and a channel region.

19. The organic light emitting diode (OLED) display of claim 18, wherein the semiconductor further includes a source electrode and a drain electrode formed on the interlayer insulating layer.

20. The organic light emitting diode (OLED) display of claim 19, wherein the source electrode and the drain electrode are electrically connected to the source region and the drain region, respectively.
